(19) United States
(12) Patent Application Publication
(10) Pub. No.: US 2025/0244206 A1
(43) Pub. Date: Jul. 31, 2025

(54) ELECTRICAL MACHINE MONITORING

(71) Applicant: ROLLS-ROYCE PLC, London (GB)

(72) Inventors: Viswanathan VAIYAPURI, Singapore (SG); Sivakumar Nadarajan, Singapore (SG); Mohamed Sathik Mohamed Halick, Singapore (SG); Rajaram Sathyanarayan, Singapore (SG); Amit K Gupta, Singapore (SG)

(73) Assignee: ROLLS-ROYCE PLC, London (GB)

(21) Appl. No.: 19/014,752

(22) Filed: Jan. 9, 2025

(30) Foreign Application Priority Data
Jan. 25, 2024 (GB) 2400995.3

(51) Int. Cl. G01M 13/04; B64F 5/60

(52) U.S. Cl. CPC G01M 13/04; B64F 5/60

(57) ABSTRACT

A method of monitoring first and second electrical machines driving respective first and second mechanical loads, the method including: measuring first and second sets of currents through a plurality of stator phases of the respective first and second electrical machines; calculating first and second DC components of a sum of squares of the respective first and second measured sets of currents; calculating a first ratio of the first DC component to the second DC component; and determining a fault in a component connected to the first or second mechanical loads if the first ratio is outside of a predetermined range.

This disclosure claims the benefit of UK Patent Application No. GB 2400995.3 filed on 25 Jan. 2024, which is hereby incorporated herein in its entirety.

### BACKGROUND

### Technical Field

The disclosure relates to monitoring of electrical machines driving mechanical loads to determine faults in components connected to the mechanical loads.

### Background of Disclosure

Urban air mobility (UAM) such as air taxis and electric vertical take-off and landing (eVTOL) vehicles are considered safety and mission critical applications. It is therefore important to ensure reliability and availability of electrical assets in such applications. So-called multi-lane systems may be used in such applications, in which two or more DC supplies provide power to respective electrical machines via power electronics converters. In UAM and eVTOL, identical high power electrical machines are used to drive multiple propulsion systems, each of which correspond to a lane of the multi-lane system. Permanent magnet electrical machines may be used because they offer a high power density, which is particularly advantageous for aerospace application. Any faults in or related to such electrical machines may, however, lead to significant damage to the machine and the associated system.

Bearing and gearbox faults can constitute a significant portion of all electrical machine faults and can be a key reason for downtime of electrical machines. Thus, an accurate detection of any such faults at an early stage is important to identify maintenance needs in advance to reduce any unscheduled down time and consequential loss of revenue.

### SUMMARY

According to a first aspect there is provided a method of monitoring first and second electrical machines driving respective first and second mechanical loads, the method comprising:
measuring first and second sets of currents through a plurality of stator phases of the respective first and second electrical machines;
calculating first and second DC components of a sum of squares of the respective first and second measured sets of currents;
calculating a first ratio of the first DC component to the second DC component; and
determining a fault in a component connected to the first or second mechanical loads if the first ratio is outside of a predetermined range.

The component may comprise a bearing and method may further comprises:
calculating first and second measurements of total harmonic distortion of the respective first and second sets of currents;
calculating a second ratio of the first and second measurements of total harmonic distortion; and
determining a fault in the bearing if the first and second ratios are outside of the predetermined range.

The method may further comprise:
determining a fault in a first bearing connected to the first mechanical load if the first and second ratios are above the predetermined range; and
determining a fault in a second bearing connected to the second mechanical load if the first and second ratios are below the predetermined range.

The predetermined range may be between around 0.95 and 1.05.

The component may comprise a gearbox, the first and second mechanical loads connected to the respective first and second electrical machines via respective first and second gearboxes, the method further comprising:
calculating first and second DC components of instantaneous space phasors (ISPs) of the respective first and second measured sets of currents through the first and second electrical machines;
calculating a second ratio of the first and second DC measurements of ISPs;
determining a fault in the gearbox if the first and second ratios are outside of the predetermined range.

The method may further comprise:
determining a fault in a first gearbox connected to the first mechanical load if the first and second ratios are above a first threshold value; and
determining a fault in a second gearbox connected to the second mechanical load if the first and second ratios are below a second threshold value.

According to a second aspect there is provided a computer program comprising instructions for causing a computer to perform the method according to the first aspect.

According to a third aspect there is provided a multi-lane electric propulsion system for an electric aircraft, the system comprising:
first and second electrical DC power supplies configured to supply first and second DC supply voltages;
first and second multi-phase electrical machines connected to drive respective first and second mechanical loads;
first and second power electronics converters configured to receive the respective first and second DC supply voltages and provide AC electrical power supplies to the first and second multi-phase electrical machines; and
a condition monitoring unit connected to measure first and second sets of currents through a plurality of stator phases of the respective first and second electrical machines,
wherein the condition monitoring unit is configured to:
calculate first and second DC components of a sum of squares of the respective first and second measured sets of currents;
calculate a first ratio of the first DC component to the second DC component; and
determine a fault in a component connected to the first or second mechanical loads if the first ratio is outside of a predetermined range.

The component may comprise a bearing and the condition monitoring unit configured to:
calculate first and second measurements of total harmonic distortion of the respective first and second sets of currents;
calculate a second ratio of the first and second measurements of total harmonic distortion; and
determine a fault in the bearing if the first and second ratios are outside of the predetermined range.

The condition monitoring unit may be configured to:
determine a fault in a first bearing connected to the first mechanical load if the first and second ratios are above the predetermined range; and
determine a fault in a second bearing connected to the second mechanical load if the first and second ratios are below the predetermined range.

The predetermined range may be between around 0.95 and 1.05.

The component may comprise a gearbox, the first and second mechanical loads connected to the respective first and second electrical machines via respective first and second gearboxes, the condition monitoring unit configured to:
calculate first and second DC components of instantaneous space phasors (ISPs) of the respective first and second measured sets of currents through the first and second electrical machines;
calculate a second ratio of the first and second DC measurements of ISPs; and
determine a fault in the gearbox if the first and second ratios are outside of the predetermined range.

The condition monitoring unit may be configured to:
determine a fault in a first gearbox connected to the first mechanical load if the first and second ratios are above a first threshold value; and
determine a fault in a second gearbox connected to the second mechanical load if the first and second ratios are below a second threshold value.

The condition monitoring unit may be configured to provide an output if a fault is determined in the component connected to the first or second mechanical loads.

The first and second electrical machines may be both permanent magnet electrical machines.

The first and second electrical machines may be both three-phase electrical machines.

The first and second electrical machines may be nominally identical.

The skilled person will appreciate that except where mutually exclusive, a feature described in relation to any one of the above aspects may be applied mutatis mutandis to any other aspect. Furthermore except where mutually exclusive any feature described herein may be applied to any aspect and/or combined with any other feature described herein.

### BRIEF DESCRIPTION OF THE DRAWINGS

Embodiments will now be described by way of example only with reference to the accompanying drawings, which are purely schematic and not to scale, and in which:

FIG. 1 is a schematic diagram of an example multi-lane electric propulsion system;

FIG. 2 is a schematic flow chart illustrating an example method of determining the presence of a bearing fault in the system of FIG. 1; and

FIG. 3 is a schematic flow chart illustrating an example method of determining the presence of a gearbox fault in the system of FIG. 1.

### DETAILED DESCRIPTION

The reliability of permanent magnet electrical machines can be improved by detecting and diagnosing any faults at an early stage to prevent failures. The availability of such electrical machines can be increased by moving from schedule-based maintenance to condition-based maintenance. Electrical machine health monitoring is a key to improving reliability and availability of such electrical machines by diagnosing any faults at an early stage and, if possible, predicting the time to failure.

Faults in permanent magnet electrical machines can be classified as electrical, mechanical and magnetic faults. In general, mechanical faults such as a bearing fault is a common fault in rotating electrical machines. This is particularly applicable to aerospace applications, in which electrical machines are required to operate at high speed and at high temperatures. This can lead to bearing or gearbox faults becoming common faults in such applications.

Described herein are detection methods for bearing and gearbox components that are based solely on electrical signatures that can be measured across the electrical machines. Compared to vibration-based techniques, electrical-based techniques do not require additional sensors, which makes such techniques potentially a preferred solution for aerospace application due to the reduced weight requirements.

Traditional methods generally use historical data to fix threshold values for the detection of electromechanical faults in electrical machines. Data at different operating conditions over the operating regime is required to allow such thresholds to be fixed. This increases the effort required on analysis and can delay offering or commercialising aerospace electrical machine solutions. The proposed methods described herein allows thresholds to be determined from a comparison between lanes of a multi-lane system instead of using historical data, which can reduce computational effort as well as remove the need for determining and processing representative historical data.

The methods proposed involve simple and accurate algorithms that can be used to detect either a fault in a bearing or gearbox in a multi-lane system. The electrical machines may be in the form of a dual-stator machine, a multiphase machine or multiple-three phase electrical machines.

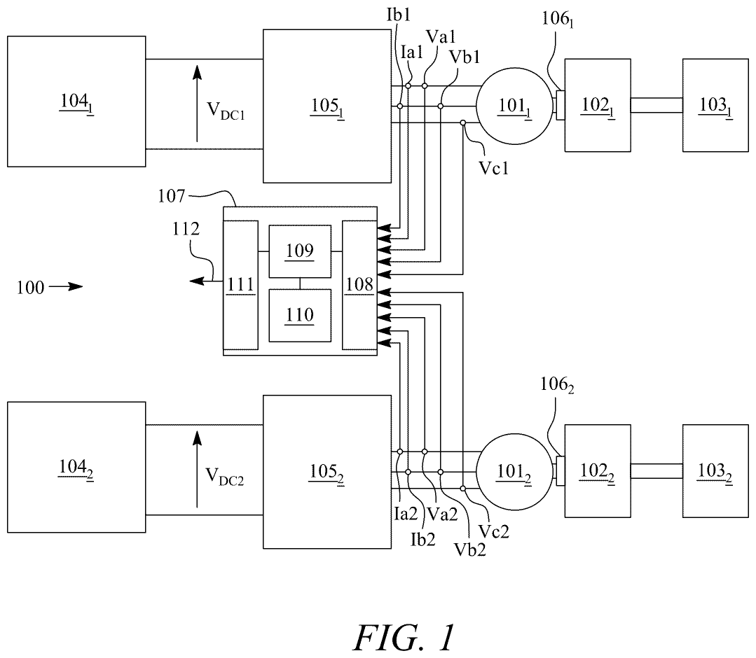

FIG. 1 illustrates an example multi-lane electric propulsion system 100 for an electric or hybrid electric aircraft. The system 100 comprises first and second electrical DC power supplies 104₁, 104₂. The DC power supplies 104₁, 104₂ may each be electrical batteries, or a common battery may provide each of the supplies 104₁, 104₂. The DC power supplies 104₁, 104₂ provide a DC supply voltage V_{DC1}, V_{DC2} to respective power electronics converters 105₁, 105₂. The DC supply voltages V_{DC1}, V_{DC2} may be of the same magnitude.

Each of the power electronics converters 105₁, 105₂ converts the DC supply voltage V_{DC1}, V_{DC2} to output AC voltage supplies to drive first and second electrical machines 101₁, 101₂. The first and second electrical machines 101₁, 101₂ may each be permanent magnet electrical machines and, for the purposes of the method described herein, are nominally identical, i.e. with the same number of phases and windings and with the same power rating.

The first and second electrical machines 101₁, 101₂ drive respective first and second mechanical loads 103₁, 103₂ via respective first and second gearboxes 102₁, 102₂. Each gearbox 103₁, 103₂ has one or more bearings 106₁, 106₂. The first and second mechanical loads 103₁, 103₂ may for example be propulsors for providing thrust and/or lift for the aircraft. In alternative examples, the electrical machines 101₁, 101₂ may be connected to the mechanical loads 103₁, 103₂ without an intervening gearbox 102₁, 102₂, but the one or more bearings 106₁, 106₂ in each lane will still be present.

Each of the electrical machines 101₁, 101₂ may have multiple windings, with the example in FIG. 1 illustrating three phases for each electrical machine 101₁, 101₂, each of which is driven by a three-phase power electronics converter 105₁, 105₂ operating as an inverter, i.e. converting the DC power supply V_{DC1}, V_{DC2} to a three phase AC supply to drive each electrical machine 101₁, 101₂.

A condition monitoring unit 107 is connected to each lane to acquire voltage and current measurements from sensors in each lane measuring currents provided to, and voltages across, each of the electrical machines 101₁, 101₂. The condition monitoring unit 107 is configured to calculate parameters from the current and voltage measurements to assess the health of the bearings and gearboxes (if present) in the system 100.

FIG. 1 further illustrates various sensors connected between the power electronics converters 105₁, 105₂ and the respective electrical machines, the sensors being configured to measure currents Ia1, Ib1 provided to the first electrical machine 101₁, currents Ia2, Ib2 provided to the second electrical machine 101₂, voltages Va1, Vb1, Vc1 at each of the phases of the first electrical machine 101₁ and voltages Va2, Vb2, Vc2 at each of the phases of the second electrical machine 101₂. Only two currents are shown in each case because the third current can be measured by being inferred from the first two in a three-phase arrangement, although in some examples this additional current may also be directly measured.

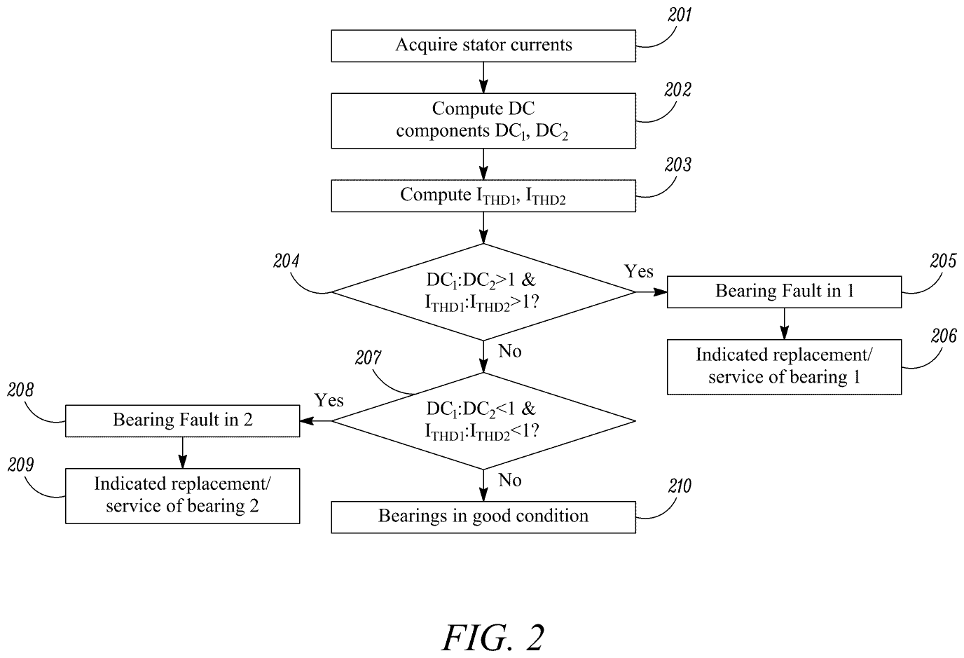

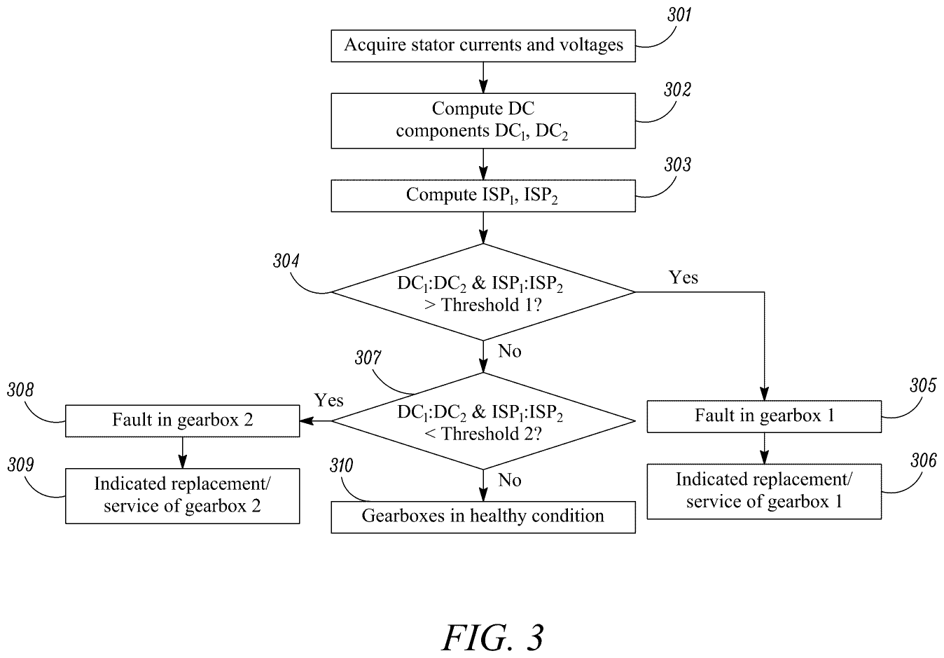

FIGS. 2 and 3 illustrate algorithms performed by the condition monitoring unit 107 to determine the presence of a fault in either a bearing or a gearbox in the system 100 of FIG. 1. The bearing fault detection algorithm in FIG. 2 requires only the electrical machine currents to be measured to detect a fault, while the gearbox fault detection algorithm in FIG. 3 uses both current and voltage measurements to detect a fault.

In the method illustrated in FIG. 2, a first step 201 is to acquire first and second sets of stator currents in the time domain for the respective first and second electrical machines 101₁, 101₂. This may be done by directly measuring each of the stator currents Ia1, Ib1, Ic1, Ia2, Ib2, Ic2 provided to each of the electrical machines 101₁, 101₂ or may be done by directly measuring all but one of the stator currents in each electrical machine and measuring the remaining current by inference from the others. In the three-phase system 100 of FIG. 1 currents Ia1, Ib1 for the first electrical machine 101₁ and Ia2, Ib2 for the second electrical machine 101₂ are measured directly and the third stator current Ic1, Ic2 is indirectly measured by being inferred from the other two currents.

In step 202, first and second DC components of a sum of squares of the respective first and second sets of currents are computed from the measured currents. These DC components DC₁, DC₂ for the respective first and second electrical machines 101₁, 101₂ are calculated according to the following equations:

$${DC}_{1} = mean \sqrt{{I}_{a 1}^{2} + {I}_{b 1}^{2} + {I}_{c 1}^{2}}$$

$${DC}_{2} = mean \sqrt{{I}_{a 2}^{2} + {I}_{b 2}^{2} + {I}_{c 2}^{2}}$$

In step 203, first and second measurements of total harmonic distortion (THD) is calculated for the respective first and second sets of currents. The THD of each current is defined as the ratio of the sum of powers of all harmonic components (i.e. all harmonics higher than the driving frequency provided by the electronics power converters 105₁, 105₂) to the power of the fundamental frequency. The THD of the currents provided to each of the first and second electrical machines 101₁, 101₂, which may be termed I_{THD1}, I_{THD2}, may therefore be determined to be the sum of THD for the currents in each of the phases.

In step 204, a first ratio between the first DC component DC₁ and the second DC component DC₂ is determined. Step 204 also comprises determining a second ratio between the first and second measurements of THD of the respective first and second sets of currents. If the first and second ratios are both greater than 1, this indicates a bearing fault connected to the first electrical machine, as indicated in step 205. In step 206 an indication may then be provided by the condition monitoring unit 107 that replacement or service of the first bearing 106₁ is required. Otherwise, the process moves to step 207. If, at step 207, the first and second ratios are determined at step 204 to be less than 1, this indicates a bearing fault connected to the second electrical machine 101₂, as indicated in step 208. In step 209 an indication may then be provided by the condition monitoring unit 107 that replacement or service of the second bearing 106₂ is required.

If, at step 207, the first and second ratios are determined to be equal to 1, the process proceeds to step 210, and the bearings are determined to be in good condition. The process may then repeat, either continuously or intermittently depending on the application requirements.

Due to operational variations and measurement inaccuracies, the ratios are unlikely to be exactly equal to 1, even when the bearings 106₁, 106₂ are in good condition. In an example implementation of the above process therefore, steps 204 and 207 involve comparing the first and second ratios to a predetermined range and determining a fault in one of the bearings 106₁, 106₂ if the first and second ratios are outside of this predetermined range. The predetermined range may for example be a small range either side of 1, for example between 0.95 and 1.05, i.e. within +/−5% of 1. The predetermined range may be selected to be different to this depending on the expected or measured variation during normal use.

In the method illustrated in FIG. 3, a first step 301 is to acquire first and second sets of stator currents in the time domain for the respective first and second electrical machines 101₁, 101₂. In addition to this, voltages Va1, Vb1, Vc1, Va2, Vb2, Vc2 for each phase of the first and second electrical machines 101₁, 101₂ are measured.

In step 302, first and second DC components of a sum of squares of the respective first and second sets of currents are computed from the measured currents. These DC components DC₁, DC₂ for the respective first and second electrical machines 101₁, 101₂ are calculated as indicated above in relation to step 202 of the bearing fault detection method.

In step 303, DC components of instantaneous space phasors (ISPs) of the currents through the first and second electrical machines are calculated. The components I₁₁, I₂₁, I₃₁ of the ISPs for a three-phase electrical machine may be calculated according to the following equations:

$${I}_{11} = {I}_{a} ( cos ( 0 ) + j sin ( 0 ) )$$

$${I}_{21} = abs [ {I}_{b} ( cos ( \frac{2 π}{3} ) + j sin ( \frac{2 π}{3} ) ) ]$$

$${I}_{31} = abs [ {I}_{c} ( cos ( - \frac{2 π}{3} ) + j sin ( - \frac{2 π}{3} ) ) ]$$

The DC component of each ISP is calculated from the sum of squares of each of the above ISP components, i.e. from Real (I₁₁+I₂₁+I₃₁)²+Img (I₁₁+I₂₁+I₃₁)².

In step 304, a first ratio between the first DC component DC₁ and the second DC component DC₂ is determined. Step 304 also comprises determining a second ratio between the first and second DC components of ISPs of the respective first and second sets of currents. If the first and second ratios are both greater than a first threshold, this indicates a gearbox fault connected to the first electrical machine, as indicated in step 305. In step 306 an indication may then be provided by the condition monitoring unit 107 that replacement or service of the first gearbox 102₁ is required. Otherwise, the process moves to step 307. If, at step 307, the first and second ratios are determined to be both less than a second threshold, this indicates a gearbox fault connected to the second electrical machine 101₂, as indicated in step 308. In step 309 an indication may then be provided by the condition monitoring unit 107 that replacement or service of the second gearbox 102₂ is required.

If, at step 307, the first and second ratios are determined to be neither above the first threshold nor below the second threshold, the process proceeds to step 310, and the gearboxes 102₁, 102₂ are determined to be in good condition. The process may then repeat, either continuously or intermittently depending on the application requirements.

As with the bearing fault monitoring process, the first and second thresholds in steps 304 and 307 may be close to 1, for example slightly above and below 1 respectively. The first and second thresholds in steps 304 and 307 may therefore together define a predetermined range. The predetermined range may be similar to the predetermined range for the bearing fault detection method or may be set differently. The predetermined range may for example be between around 0.95 and 1.05, i.e. with the first threshold at around 1.05 and the second threshold at around 0.95. Other values may apply depending on the application requirements and measurement accuracies.

The above-described methods are implemented on the condition monitoring unit 107. The condition monitoring unit 107 may be a general purpose computer unit comprising an input interface 108 configured to receive the current and voltage signals from the first and second electrical machines 101₁, 101₂, a processor 109 for processing the signals, calculating the required components and ratios and determining the presence or absence of faults, a memory 110 for storing instructions, sensor data and calculation outputs, and an output interface 111 for providing an output indication 112 to an external unit.

According to an aspect of the invention there is provided a computer program comprising instructions for causing a computer, i.e. the condition monitoring unit, to perform the methods as described herein. The computer program may be a software implementation, and the computer may be considered as any appropriate hardware, including a digital signal processor, a microcontroller, and an implementation in read only memory (ROM), erasable programmable read only memory (EPROM) or electronically erasable programmable read only memory (EEPROM), as non-limiting examples. The software implementation may be an assembly program.

The computer program may be provided on a non-transitory computer readable medium, which may be a physical computer readable medium, such as a disc or a memory device, or may be embodied as a transient signal. Such a transient signal may be a network download, including an internet download.

1. A method of monitoring first and second electrical machines driving respective first and second mechanical loads, the method comprising:
measuring first and second sets of currents through a plurality of stator phases of the respective first and second electrical machines;
calculating first and second DC components of a sum of squares of the respective first and second measured sets of currents;
calculating a first ratio of the first DC component to the second DC component; and
determining a fault in a component connected to the first or second mechanical loads if the first ratio is outside of a predetermined range.

2. The method of claim 1, wherein the component comprises a bearing and method further comprises:
calculating first and second measurements of total harmonic distortion of the respective first and second sets of currents;
calculating a second ratio of the first and second measurements of total harmonic distortion; and
determining a fault in the bearing if the first and second ratios are outside of the predetermined range.

3. The method of claim 2, further comprising:
determining a fault in a first bearing connected to the first mechanical load if the first and second ratios are above the predetermined range; and
determining a fault in a second bearing connected to the second mechanical load if the first and second ratios are below the predetermined range.

4. The method of claim 1, wherein the predetermined range is between around 0.95 and 1.05.

5. The method of claim 1, wherein the component comprises a gearbox, the first and second mechanical loads are connected to the respective first and second electrical machines via respective first and second gearboxes, the method further comprising:
calculating first and second DC components of instantaneous space phasors, ISPs, of the respective first and second measured sets of currents through the first and second electrical machines;
calculating a second ratio of the first and second DC measurements of ISPs;
determining a fault in the gearbox if the first and second ratios are outside of the predetermined range.

6. The method of claim 5, further comprising:
determining a fault in a first gearbox connected to the first mechanical load if the first and second ratios are above a first threshold value; and
determining a fault in a second gearbox connected to the second mechanical load if the first and second ratios are below a second threshold value.

7. A computer program comprising instructions for causing a computer to perform the method according to claim 1.

8. A multi-lane electric propulsion system for an electric aircraft, the system comprising:
first and second electrical DC power supplies configured to supply first and second DC supply voltages;
first and second multi-phase electrical machines connected to drive respective first and second mechanical loads;
first and second power electronics converters configured to receive the respective first and second DC supply voltages and provide AC electrical power supplies to the first and second multi-phase electrical machines; and
a condition monitoring unit connected to measure first and second sets of currents through a plurality of stator phases of the respective first and second electrical machines,
wherein the condition monitoring unit is configured to:
calculate first and second DC components of a sum of squares of the respective first and second measured sets of currents;
calculate a first ratio of the first DC component to the second DC component; and
determine a fault in a component connected to the first or second mechanical loads if the first ratio is outside of a predetermined range.

9. The system of claim 8, wherein the component comprises a bearing and the condition monitoring unit is configured to:
calculate first and second measurements of total harmonic distortion of the respective first and second sets of currents;
calculate a second ratio of the first and second measurements of total harmonic distortion; and
determine a fault in the bearing if the first and second ratios are outside of the predetermined range.

10. The system of claim 9, wherein the condition monitoring unit is configured to:
determine a fault in a first bearing connected to the first mechanical load if the first and second ratios are above the predetermined range; and
determine a fault in a second bearing connected to the second mechanical load if the first and second ratios are below the predetermined range.

11. The system of claim 8, wherein the predetermined range is between around 0.95 and 1.05.

12. The system of claim 8, wherein the component comprises a gearbox, the first and second mechanical loads are connected to the respective first and second electrical machines via respective first and second gearboxes, the condition monitoring unit configured to:
calculate first and second DC components of instantaneous space phasors, ISPs, of the respective first and second measured sets of currents through the first and second electrical machines;
calculate a second ratio of the first and second DC measurements of ISPs; and
determine a fault in the gearbox if the first and second ratios are outside of the predetermined range.

13. The system of claim 12, wherein the condition monitoring unit is configured to:
determine a fault in a first gearbox connected to the first mechanical load if the first and second ratios are above a first threshold value; and
determine a fault in a second gearbox connected to the second mechanical load if the first and second ratios are below a second threshold value.

14. The system of claim 8, wherein the condition monitoring unit is configured to provide an output if a fault is determined in the component connected to the first or second mechanical loads.

15. The system of claim 8, wherein the first and second electrical machines are both permanent magnet electrical machines.

16. The system of claim 8, wherein the first and second electrical machines are both three-phase electrical machines.

17. The system of claim 8, wherein the first and second electrical machines are nominally identical.
